(19) United States
(12) Patent Application Publication
(10) Pub. No.: US 2002/0168480 A1
(43) Pub. Date: Nov. 14, 2002

(54) Surface modified silica by plasma polymerization, preparation method and apparatus thereof

(76) Inventors: Tae-Ho Yoon, Kwangju (KR); Joon Ho Roh, Kwangju (KR)

Correspondence Address: FINNEGAN, HENDERSON, FARABOW, GARRETT &, DUNNER LLP, 1300 I STREET, NW, WASHINGTON, DC, 20005, US

(21) Appl. No.: 09/884,906

(22) Filed: Jun. 21, 2001

(30) Foreign Application Priority Data
Mar. 20, 2001 (KR) 2001-14393

(51) Int. Cl. H05H 1/24; C23C 16/00

(52) U.S. Cl. 427/488; 427/569; 118/723 I

(57) ABSTRACT

This invention relates to the surface modified silica by plasma polymerization coating, plasma polymerization method and plasma polymerization devices. Silica, active ingredients of EMC, is coated by plasma polymerization coating in order to enhance the adhesion of silica to epoxy resin and thus to improve the reliability of EMC. The monomers for the plasma polymerization coating were 1,3-diaminopropane, allylamine, pyrrole, 1,2-epoxy-5-hexene, allylmercaptan and allylalcohol, and the surface modified silica was utilized to prepare EMC for electronic devices. The plasma polymerization coating, which is known to be environment-friendly method, provided excellent flexural properties of EMC compared to the conventionally prepared EMC.

### BACKGROUND OF THE INVENTION

### FIELD OF THE INVENTION

This invention relates to the surface modified silica by plasma polymerization coating, plasma polymerization method and plasma polymerization devices in order to enhance the adhesion between silica and epoxy resin, major ingredients of epoxy molding compound(EMC). Silica was coated by plasma polymerization coating with one monomer selected from 1,3-diaminopropane, allylamine, pyrrole 1,2-epoxy-5-hexene, allylmercaptan and allylalcohol and subjected to preparation of EMC in order to provide excellent adhesion between the coated silica and epoxy resin, and thus excellent properties of EMC compare with conventional method. The monomers containing amine functional groups may generate chemical bonds with epoxy resin.

Epoxy molding compound (EMC), consisting of silica and epoxy resin as major ingredients, is utilized to protect electronic devices such as chips from environmental damages. Based upon the excellent properties of epoxy resin, (electrical and mechanical properties, and chemical and thermal stability), EMC was adopted as a molding compound for microelectronic devices since 1960s and currently more than 90% of devices use EMC as a package.

Recently, since the semiconductor devices are getting smaller and lighter, the reliability of EMC is more important than ever before. Moreover, the semiconductor devices are heated to above 200□ when they are being mounted, resulting in cracking and thus delamination of EMC due to the CTE mismatch. This phenomenon is even worse if moisture is present, which is usually absorbed into EMC.

Therefore, in order to improve the reliability of EMC, better properties (e.g., good mechanical property, low coefficient of thermal expansion, and low water absorption, etc.) are required.

The conventional technologies for improving the reliability of EMC have focused on the lowering of residual stress by matching the CTE of EMC to that of die-pad. This can be achieved by maximizing the loading of silica in EMC and thus adhesion of silica to epoxy resin becomes a critical factor.

In an effort to improve the adhesion of silica to epoxy resin, silane coupling agents have been widely utilized since they are known to form chemical bonds between silica and epoxy resin.

There are three ways to modify the surface of silica with silane coupling agents: (1) a pretreatment method (PM): silica is coated, dried and powdered, (2) an internal pretreatment method (IPM): silica is coated, but no dry and no powdering process, and (3) an integral addition method (IAM): silane and silica are added to epoxy resin without pre-coating.

Concerning the properties, the PM provides the best adhesion, but it requires a removal process of solvent (alcohol and water) after surface treatment, and drying and powdering process in order to prevent aggregation of silica. Therefore, the PM takes long process time and thus high processing cost, comparing to other methods.

On the other hand, IPM does not have drying and powdering processes and thus it takes much shorter processing time compare to PM. However, since solvent on the silica surface does not have a chance to evaporate (no drying process), aggregation of silica and decomposition of solvent are often experienced.

In IAM, since silica is not coated with silane, but added into the epoxy resin, it is very simple process and no solvent is involved, but it provides relatively poor adhesion, compared with PM and IPM.

However, the modification of silica with silane coupling agent also has a number of disadvantages; (1) use of solvent may cause an environmental pollution, (2) treatment process is complicated, and (3) silica may aggregate and silane decomposes due to hydrolysis and condensation of silane coupling agent after treatment, resulting in deterioration of EMC properties.

Therefore, a number of researchers have tired to find new way of silica surface modification which is environment-friendly method and thus can substitute silane coupling agent.

Yashuda (Plasma Polymerization, Academic Press, New York, 1985) has reported that plasma polymer films have unique properties such as good adhesion to various substrates, low permeability of oxygen and water vapor, and high resistance to solvents due to their crosslnked nature.

Tsai and van Ooij have also indicated that plasma polymerization with acetylene gas greatly enhanced adhesion of rubber to steel plate due to the chemical bonds formed by C═C groups in plasma polymer films (Surface and Interface Analysis, Vol. 23, pp. 261-275, 1995).

### SUMMMARY OF THE INVENTION

As such, the conventional method for improving the properties of EMC via surface modification of silica with silane coupling agent has a number of drawbacks; (1) the use of solvent may cause an environmental pollution, (2) treatment process is complicated, and (3) silica may aggregate and silane decomposes due to hydrolysis and condensation of silane coupling agent after treatment, resulting in deterioration of EMC properties.

In order to improve the reliability of EMC, environment-friendly and economically feasible surface modification method has to be developed.

The inventor has reported that highly enhanced adhesion of steel tire cords to rubber was achieved by the acetylene plasma polymerization coating (H. M. Kang, K. H. Chung, S. Kaang and T. H. Yoon, Elastomer (Korea), Vol. 35, No. 1, pp. 53-62, 2000).

This invention has adapted plasma polymerization coating technique to enhance(d) adhesion of silica to epoxy resin and thus the properties of EMC.

To be free from the aforementioned shortcomings, an object of this invention is to provide surface modification method for silica in order to enhance the adhesion to epoxy resin. Silica is coated by plasma polymerization coating with one monomer selected from 1,3-diaminopropane, allylamine, pyrrole 1,2-epoxy-5-hexene, allylmercaptan and allylalcohol, and subjected to preparation of EMC in order to provide good properties of EMC compare with conventional method. The monomers containing amine functional groups may generate chemical bonds with epoxy resin.

Another object of this invention is to prepare EMC with excellent properties for semiconductor package by using plasma polymer coated silica.

### BRIEF DESCRIPTION OF THE DRAWINGS

FIG. 1 is a schematic diagram of plasma polymerization coating device for the surface modification of silica for EMC according to this invention.

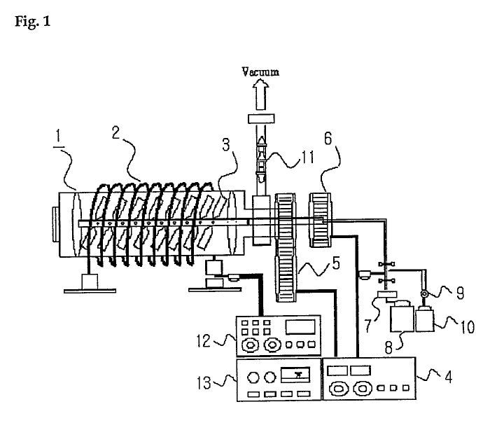

### [Explanation of Main Codes in the Drawings]

1: Tubular reactor

2: RF coil

3: Mixing blade

4: Tubular reactor controller

5: First gear

6: Second gear

7: Mass flow controller

8: Gas container

9: Needle valve

10: Bubbler

11: Filter

12: Impedance matching unit

13: RF power supply unit

### DETAILED DESCRIPTION OF THE INVENTION

This invention is characterized by surface modification of silica for EMC which is used for semiconductor package, wherein the surface of silica is coated via plasma polymerization coating of 1,3-diaminopropane, allylamine, pyrrole, 1,2-epoxy-5-hexene, allylmercaptan and allylalcohol.

This invention is also characterized by a surface modification method of silica for EMC, wherein plasma polymerization coating of silica comprises the steps of:

1) charging of silica with average diameter of 25-35 □ into a plasma polymerization reactor 1, followed by vacuuming to 1×10⁻³ torr;

2) introducing monomer (1,3-diaminopropane, allylamine, pyrrole, 1,2-epoxy-5-hexene, allylmercaptan or allylalcohol) into the reactor via steel pipe; and,

3) rotating the reactor at 1-50 rpm at plasma polymerization conditions: plasma powder (10-40 W), gas pressure (40-50 mtorr) and treatment time (20-40 seconds).

Since the chemical structure of the monomer are different, the plasma polymerization conditions have to be optimized for each monomer.

This invention is also characterized by the plasma polymerization device for silica for EMC, wherein it comprises:

tubular reactor 1 where RF coil 2 is rolled outside of the tubular reactor;

mixing blade 3 with wings on both sides is installed inside of the reactor and is deigned to rotate to the opposite direction of the reactor;

the tubular reactor is operated by #1 gear 5 and #2 gear 6 which are controlled by the controller 4; and

the monomer for plasma polymerization was supplied form container 8 with mass flow controller 7 or bubbler 10 with a needle valve 9.

The reactor 1 is equipped with filter 11 which can serve to prevent the inflow of silica powder into vacuum pump.

Further, impedance matching unit 12 for the optimum plasma generation and RF power supply unit 13 are also equipped.

The tubular reactor 1 of Pyrex with a length of 360 mm and a diameter of 100 mm is designed to revolve via the #1 gear 5.

Mixing blade 3 is inserted into the tubular reactor, which is designed to rotate to the opposite direction of Pyrex reactor in order to have uniform coating of silicon powder.

Further, this invention is characterized by EMC for semiconductor package, consisting of epoxy resin, hardener, promoter and silica which was modified by plasma polymerization coating.

The surface modification of silica enhances the adhesion to with epoxy resin and thus improve the properties of EMC.

The EMC for semiconductor package is prepared as follows:

Epoxy resin, hardener and promoter are mixed at 150□ for 3 mninutes. Then, plasma polymer coated silica was charged into the resin mixture and stirred for 5 minutes, followed by pouring into silicon rubber mold. The resin mixture was placed in a vacuum oven of 130□ and degassed for 3 minutes, followed by curing in an air-convection oven of 175□ for 4 hours.

As mentioned above, the surface modification of silica by plasma polymerization coating is carried out to enhance the adhesion of silica with epoxy resin, and thus improve the properties of EMC for semiconductor package.

The following specific examples are intended to illustrate this invention but these illustrations do not limit the scope of this invention as defined by appended claims.

### Examples 1-6

### Surface modification of silica

As shown in Table 1, the conditions for the plasma polymerization coating were optimized as a function of plasma power, gas pressure and treatment time. The optimization process with plasma polymerization method and plasma polymerization devices is as follows.

1) Fused-spherical silica (30 g) was charged into the tubular reactor, followed by vacuuming to 1×10⁻³ torr. While the blade inside of the tubular reactor was rotated at 50 rpm, 1,3-diaminopropane (Example 1) was introduced into the reactor through the needle valve to make the internal reactor pressure of 40 mtorr.

2) The plasma power was optimized first by varying from 20, 30, 40 to 50W under fixed gas pressure (40 mtorr) and treatment time (30 sec) via measuring the flexural strength of EMC. The optimum plasma power for 1,3-diaminopropane was 40 W, at which the highest flexural strength was obtained.

3) The gas pressure was also optimized by varying from 30, 40 to 50 mtorr under fixed plasma power (40 W) and treatment time (30 sec). The optimum gas pressure was 40 mtorr.

4) The treatment time was optimized again by varying from 30, 60 to 90 sec under fixed plasma power (40 W) and gas pressure (40 mtorr). As the treatment time increased, the flexural strength decreased. In this respect the optimum treatment time can be said to be 30 sec.

Therefore, the optimum plasma polymerization conditions for 1,3-diaminopropane were 40 W, 40 mtorr and 30 sec.

Since the monomers used for this invention have different chemical structure, the plasma polymerization conditions for each monomer were needed to be optimized. Thus the optimization was carried out for allyamine (Example 2), pyrrole (Example 3), 1,2-epoxy-5-hexene (Example 4), allylmercaptan (Example 5) and allylalcohol (Example 6). The surface modification of silica was performed at the optimum plasma polymerization conditions in order to prepare the EMC (Example 1-6).

TABLE 1

Example

| Category | | 1 | 2 | 3 | 4 | 5 | 6 |
|---|---|---|---|---|---|---|---|
| Reaction | Plasma power (W) | 40 | 30 | 30 | 10 | 30 | 30 |
| conditions | | | | | | | |
| | Gas pressure (mtorr) | 40 | 40 | 50 | 40 | 40 | 40 |
| | Treatment time (sec) | 30 | 30 | 30 | 30 | 30 | 30 |

### Example 7-8

In order to investigate the stability of plasma polymer coating, the surface modified silica samples from Examples 1 and 2 were aged in the lab atmosphere for 1, 3, 7 or 15 days. The ageing of samples was carried out by placing by plasma polymer coated silica (30 g) in a 1000 ml beaker and covered with Kimwipe.

### Example 9-16 and comparative example 1

### Preparation of EMC

As shown in Table 2, epoxy resin, hardener and promoter were mixed at 150□ for 3 minutes. Then, surface modified silica (Examples 1-8) or unmodified silica were charged into the resin mixture, followed by stirring for 5 minutes to get homogenous mixture and then pouring into silicon rubber mold. In order to remove any volatiles which may form bubbles and thus lowering flexural strength, the resin mixture was degassed in a vacuum oven of 130□ for 3 minutes and then, cured in an air-convention oven of 175□ for 4 hours.

TABLE 2

| | | | | | | | | | | | Com. |
|---|---|---|---|---|---|---|---|---|---|---|---|
| | | | Example | | | | | | | | Exp. |
| Category | | | 9 | 10 | 11 | 12 | 13 | 14 | 15 | 16 | 1 |
| Composition (□) | Silica | Exp. □ | 24 | | | | | | | | |
| | | Exp. □ | | 24 | | | | | | | |
| | | Exp. □ | | | 24 | | | | | | |
| | | Exp. □ | | | | 24 | | | | | |
| | | Exp. □ | | | | | 24 | | | | |
| | | Exp. □ | | | | | | 24 | | | |
| | | Exp. □ | | | | | | | 24 | | |
| | | Exp. □ | | | | | | | | 24 | |
| | | Silica | | | | | | | | | 24 |

| | | | | | | | | | |
|---|---|---|---|---|---|---|---|---|---|
| Epoxy Resin¹⁾ | 10.19 | 10.19 | 10.19 | 10.19 | 10.19 | 10.19 | 10.19 | 10.19 | 10.19 |
| Hardener²⁾ | 5.78 | 5.78 | 5.78 | 5.78 | 5.78 | 5.78 | 5.78 | 5.78 | 5.78 |
| Promoter³⁾ | 0.03 | 0.03 | 0.03 | 0.03 | 0.03 | 0.03 | 0.03 | 0.03 | 0.03 |

¹⁾Biphenyl type epoxy
²⁾Phenol novolac
³⁾Triphenylphosphine

### Experimental examples 1-7

The properties of EMC, prepared from Examples (9-14) and Comparative example 1 were evaluated by the test method as follow;

1. The flexural strength of EMC was measured with a sample of 3×10×60 mm by 3-point banding according to ASTM D 790.

2. The CTE of EMC was measured by TMA in a glassy stat (lower than Tg) and in a rubbery state (higher than Tg).

3. The water absorption of EMC was evaluated by exposing in a pressure cooker of 121□, 2 atm and 100% RH for 8, 16, 24 and 32 hours. Three specimens (3×10×60 mm) were evaluated

The results of property measurements are shown in Table 3.

TABLE 3

| | | Flexural | Flexural | | | | | | |
|---|---|---|---|---|---|---|---|---|---|
| | | strength | strength | | | | | | |
| | | at room | at | CTE (μm/m□) | | Water absorption (wt %) | | | |
| Cate- | | temp | 250□(MP | Glassy | Rubber | | 16 | 24 | 32 |
| gory | Sample | (MPa) | a) | region | region | 8 hr | hr | hr | hr |
| Test 1 | Exp. 9 | 167 ± 3 | 7.5 ± 0.5 | 42 | 128 | 0.50 | 0.66 | 0.70 | 0.70 |
| Test 2 | Exp. 10 | 165 ± 4 | 7.2 ± 0.8 | 39 | 128 | 0.49 | 0.64 | 0.71 | 0.71 |
| Test 3 | Exp. 11 | 157 ± 3 | 5.6 ± 0.7 | 33 | 133 | 0.55 | 0.72 | 0.78 | 0.75 |
| Test 4 | Exp. 12 | 154 ± 3 | 5.7 ± 0.9 | 37 | 135 | 0.49 | 0.69 | 0.77 | 0.76 |
| Test 5 | Exp. 13 | 152 ± 5 | 6.0 ± 0.3 | 38 | 143 | 0.58 | 0.75 | 0.74 | 0.76 |
| Test 6 | Exp. 14 | 148 ± 5 | 5.5 ± 0.4 | 33 | 140 | 0.56 | 0.68 | 0.76 | 0.76 |
| Test 7 | Comp. | 140 ± 5 | 5.6 ± 0.7 | 35 | 145 | 0.54 | 0.70 | 0.81 | 0.81 |
| | Exp. 1 | | | | | | | | |

From Table 3, the flexural strengths of EMCs prepared from Examples 9-14, were higher than that of control sample (Comparative example 1). Furthermore, the Cm and water absorption of EMCs prepared from Examples 9-14 were superior to those of control sample (Comparative example 1).

### Experimental examples 8-9

### Flexural strength of EMC by aging of cilica

The stability of the functional groups in the plasma polymer coating was evaluated by measuring the flexural strength of EMC which was prepared from aged silica after plasma polymerization coating (Examples 1 and 2) and the results are shown in Table 4.

TABLE 4

| | | Flexural strength (Mpa) | | | | |
|---|---|---|---|---|---|---|
| | | Aging time (day) | | | | |
| Category | Specimen | 0 | 1 | 3 | 7 | 15 |
| Test 8 | Exp. 15 | 167 ± 3 | 167 ± 4 | 167 ± 5 | 165 ± 4 | 165 ± 2 |
| Test 9 | Exp. 16 | 165 ± 4 | 163 ± 4 | 164 ± 5 | 165 ± 4 | 165 ± 4 |

As observed from Table 4, the flexural strengths of EMCs do not change with aging time and thus it can be said that the plasma polymer coating (or functional groups in the coating) is very stable even after 15 days of aging.

As described above, silica, a major ingredient of EMC, is coated by plasma polymerization coating which is known to be environmentally-friendly technique. The monomers for plasma polymerization were 1,3-diaminopropane, allylamine, pyrrole 1,2-epoxy-5-hexene, allylmercaptan and allylalcohol. The EMC samples with plasma polymer coated silica provided excellent flexural properties, and thus this EMC can be utilized as a package for semiconductors.

What is claimed is:

1. Surface modified silica for EMC by plasma polymerization coating with one of following monomers; 1,3-diaminopropane, allylamine, pyrrole 1,2-epoxy-5-hexene, allylmercaptan and allylalcohol.

2. A method of plasma polymerization coating of silica:
1) charging of silica with average diameter of 25-35 □ into a plasma polymerization reactor 1, followed by vacuuming to 1×10⁻³ torr;
2) introducing monomer (1,3-diaminopropane, allylamine, pyrrole, 1,2-epoxy-5-hexene, allylmercaptan or allylalcohol) into the reactor via steel pipe; and,
3) rotating the reactor at 1-50 rpm at plasma polymerization conditions: plasma powder (10-40 W), gas pressure (40-50 mtorr) and treatment time (20-40 seconds).

3. A device for the plasma polymerization coating of silica for EMC:
the tubular reactor 1 of Pyrex with a length of 360 mm and a diameter of 100 mm is designed to revolve via the #1 gear 5.
tubular reactor 1 where RF coil 2 is rolled around outside of rotating cylindrical body;
mixing blade 3 with wings on both sides is installed inside of the reactor and is deigned to rotated to the opposite direction of the reactor;
the tubular reactor is operated by #6b 1 gear 5 and #2 gear 6 which are controlled by the controller 4; and
the monomer for plasma polymerization was supplied form container 8 with mass flow controller 7 or bubbler 10 with a needle valve 9.

4. For EMC containing epoxy resin, hardener, promoter and silica for semiconductor package, wherein the silica is used for EMC was prepared by the method described in claim #1.
